(19) United States
(12) Patent Application Publication
(10) Pub. No.: US 2021/0383185 A1
(43) Pub. Date: Dec. 9, 2021

(54) Biometric Sensor Module for a Chip Card, and Method for Manufacturing Such a Module

(71) Applicant: Linxens Holding, Mantes-La-Jolie (FR)

(72) Inventors: Christophe Mathieu, Mantes-La-Jolie (FR); Claire Laurens De Lopez, Mantes-La-Jolie (FR); Sebastien Germain, Mantes-La-Jolie (FR)

(73) Assignee: Linxens Holding

(21) Appl. No.: 17/336,502

(22) Filed: Jun. 2, 2021

(30) Foreign Application Priority Data
Jun. 4, 2020 (FR) 2005877

(51) Int. Cl. G06K 19/073; H01L 25/18; H01L 25/065; H01L 27/146; H01L 25/00

(52) U.S. Cl. CPC G06K 19/07354; H01L 25/18; H01L 25/0657; H01L 2225/06517; H01L 25/50; H01L 27/1469; H01L 2225/0651; H01L 27/14634

(57) ABSTRACT

Method for manufacturing a biometric sensor module for a chip card, including steps of
providing a dielectric substrate having a front face and a back face, and
attaching a biometric sensor for fingerprint detection to the back face, a detection area covered by the sensor on the back face being placed opposite a detection area configured such that a finger is placed on it. At least at the surface of the surface of this detection area, the dielectric substrate has an exposed homogeneous polymer material.

### TECHNICAL FIELD

The invention relates to the field of chip cards.

### PRIOR ART

In the field of chip cards, and notably in that of chip cards used as payment means, manufacturers are always wishing to offer users greater security and/or ease of use. It has thus been proposed to integrate biometric sensors for reading fingerprints into chip cards. To detect fingerprints, such sensors comprise a detection element formed of a set of sensitive elements (for example capacitive elements), generally arranged in rows and columns underneath a detection area.

For cards benefiting from contact-based and contactless read modes, a module integrated into the card and comprising a biometric sensor may allow a transaction to be authorized only if the fingerprint of the card holder is detected. This type of card is described for example in the patent document published under the number EP 3 336 759 A1. To produce such a card, a cavity is milled into the card so as to expose an electrical circuit integrated beforehand into the body of the card and house the module there. The module then housed in this cavity is also electrically connected to the circuit.

It has been observed that the detection area on which a finger has to be placed in order for the fingerprint to be recognized is subject to a certain number of factors (humidity, sweat, mechanical abrasion, UV aging, temperature, etc.) that are liable to degrade and/or prematurely wear the detection element. It may be contemplated to cover the surface of the detection area with a protective layer. However, it is then necessary to find a material that makes it possible, all at once, to increase resistance to the aggressive factors to which the detection area is subject, also makes it possible not to interfere with the detection of the fingerprint, but is also compatible with all of the other steps of manufacturing, processing and embedding the biometric module.

The invention aims to find a solution for at least partially improving the protection of the detection area, and if possible without sacrificing the appearance of the detection area visible on the surface of the card.

### SUMMARY OF THE INVENTION

What is thus proposed according to the invention is a biometric sensor module for a chip card, comprising
a dielectric substrate having an outer face and an inner face, each situated respectively on either side of this dielectric substrate considered along its thickness, the inner and outer faces of the substrate corresponding to the main faces of the substrate,
tracks and connection pads formed in a sheet of electrically conductive material that rests on the inner face of the substrate and is fastened thereto,
a biometric sensor with a detection element formed of sensitive elements, this sensor being connected to at least some pads, and being fastened to an area of the inner face that does not have any electrically conductive material, an area of the outer face situated opposite the detection element corresponding to a biometric detection area, and
an encapsulation deposited at least on the sensor, on the side of the inner face of the substrate.

Furthermore, in this module, at least over the detection area, the outer face of the substrate corresponds to a homogeneous polymer material that is exposed and that has a glass transition temperature greater than or equal to 110 degrees Celsius.

Indeed, a homogeneous polymer material, unlike glass epoxy for example, does not contain any fibres liable to interfere with the biometric measurement, whether this be a capacitive, optical, ultrasound or thermal biometric measurement. For example, this homogeneous polymer material is a polyimide, a polyethylene naphthalate (PEN) or a polyetheretherketone (PEEK). Moreover, having a glass transition temperature greater than 110° Celsius makes it possible to implement certain soldering and/or connection techniques and materials (for example: solder paste, solder, anisotropic conductive film ACF, etc.) for the electrical connection between the biometric sensor module and an electrical circuit integrated into the body of the chip card, and to implement certain assembly and/or embedding methods comprising steps which involve heating. This homogeneous polymer material is preferably opaque and for example black in colour.

The homogeneous polymer material is mechanically resistant (for example to the abrasion of a finger placed repeatedly on the detection area). The homogeneous polymer material is also chemically resistant (for example to acidic or basic sweat, but also to solvents such as fuel, ethanol or other solvents mentioned in the ISO10373-1 standard). The homogeneous polymer material has a relative dielectric permittivity, at ambient temperature and at 1 kHz, for example of the order of 2 to 4, and preferably between 3 and 3.5. The dielectric substrate may consist integrally of one and the same layer of the same homogeneous polymer material. In this case, its thickness is for example between 25 and 75 micrometres (for example 50 micrometres). This embodiment makes it possible to use a single material to protect the sensitive elements of the sensor and to produce the substrate forming the support for the sensor and for the connections of the sensor to an electrical circuit situated in the body of the chip card. As an alternative, if the dielectric substrate consists of multiple layers, said homogeneous polymer material left exposed at least over the detection area covers the surface of the outer face corresponding to this detection area. When the dielectric substrate consists of multiple layers of homogeneous polymer material, these various layers advantageously have the same relative dielectric permittivity, or relative dielectric permittivities that are close and between 2 and 4, at ambient temperature and at 1 kHz, and preferably between 3 and 3.5 at ambient temperature and at 1 kHz.

The homogeneous polymer material may be bulk-coloured, notably in black, so as to give the card an aesthetic touch. The layer of homogeneous polymer material thus protects the sensitive elements of the detection element, without interfering with the fingerprint capturing, while at the same time making it possible to provide potential extra aesthetic value. The layer of homogeneous polymer material provides these advantages without it being necessary to add another protective layer to the outer surface of the substrate, for example.

This chip card module optionally comprises one and/or another of the following features, each considered independently of one another, or each in combination with one or more others:
the sensor is fastened to the inner face of the dielectric substrate using an adhesive layer the thickness of which is between 5 and 35 micrometres; and
the module has first connection pads that are electrically connected to the sensor and that are located underneath the encapsulation and second connection pads that are electrically connected to the first connection pads, these second pads being intended to connect the module to a chip card circuit and being located outside the encapsulation.

According to another aspect, the invention relates to a chip card comprising a biometric sensor module according to the invention. This chip card comprises a card body with an electrical circuit integrated into the card body. The module and the circuit are electrically connected to one another using a solder material deposited on connection pads.

According to yet another aspect, the invention relates to a method for manufacturing a biometric sensor module for a chip card, comprising steps of
providing a dielectric substrate having an outer face and an inner face, each situated respectively on either side of this dielectric substrate considered along its thickness, the inner and outer faces of the substrate corresponding to the main faces of the substrate,
forming tracks and connection pads in a sheet of electrically conductive material before or after this layer of electrically conductive material has been fastened to the inner face of the substrate,
fastening a biometric sensor with a detection element formed of sensitive elements to an area of the inner face that does not have any electrically conductive material, an area of the outer face situated opposite the detection element corresponding to a biometric detection area,
connecting the sensor to at least some pads, and
encapsulating the sensor in an encapsulation.

Furthermore, at least over the detection area, the outer face of the substrate corresponds to a homogeneous polymer material left exposed.

### BRIEF DESCRIPTION OF THE FIGURES

Further aspects, aims and advantages of the invention will become apparent from reading the following detailed description, and with reference to the appended drawings, which are given by way of non-limiting examples and in which:

FIG. 1 schematically shows a perspective view of a chip card according to one example of an embodiment of the invention;

FIG. 2a to FIG. 2d schematically show a sectional view of various steps of one example of a method for manufacturing a biometric sensor module, such as the one integrated into the card shown in FIG. 1; and

FIG. 3 schematically shows a sectional view of the integration of a biometric sensor module, obtained using a method such as the one illustrated by FIGS. 2a to 2d, into a card.

### DETAILED DESCRIPTION

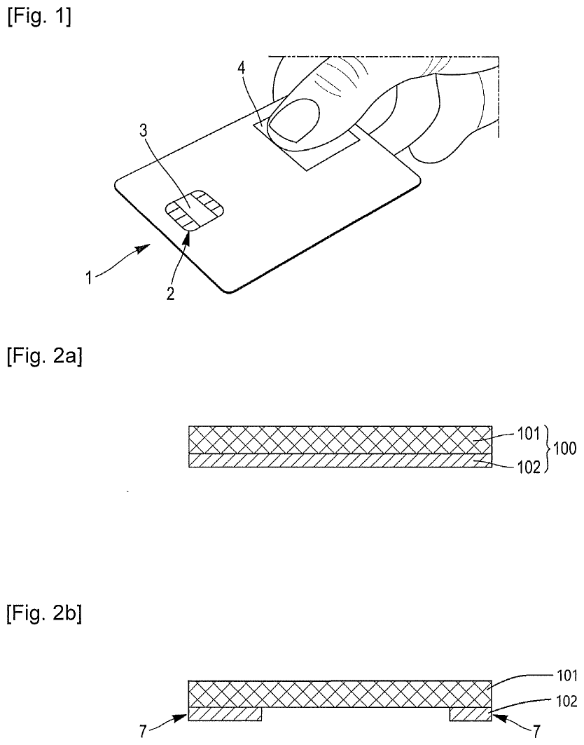

One example of a chip card 1 according to the invention is shown in FIG. 1. In this example, the card 1 is a bank card in the ID-1 format. This card 1 has a first module 2 comprising a connector 3 and an electronic chip (underneath the connector). The connector 3 makes it possible to electrically connect the electronic chip to a card reader in order to exchange data between the chip and the card reader.

In the case of dual-interface cards, that is to say allowing contact-based or contactless reading, this card 1 also has an antenna integrated into the body of the card 1. This antenna is connected for example to the chip situated in the first module 2. This antenna allows the contactless exchange of data between the chip and a contactless card reader. This antenna, or another part of an electrical circuit situated in the body of the card 1, is also electrically connected to a second module 4 integrated into the card 1. The second module 4 is a biometric module. This biometric module 4 comprises a sensor for fingerprint recognition. The second module 4 makes it possible to determine whether the fingerprint read by the sensor corresponds to that of a user authorized to use this card 1. In this case, contactless communication between the chip and a reader may be authorized.

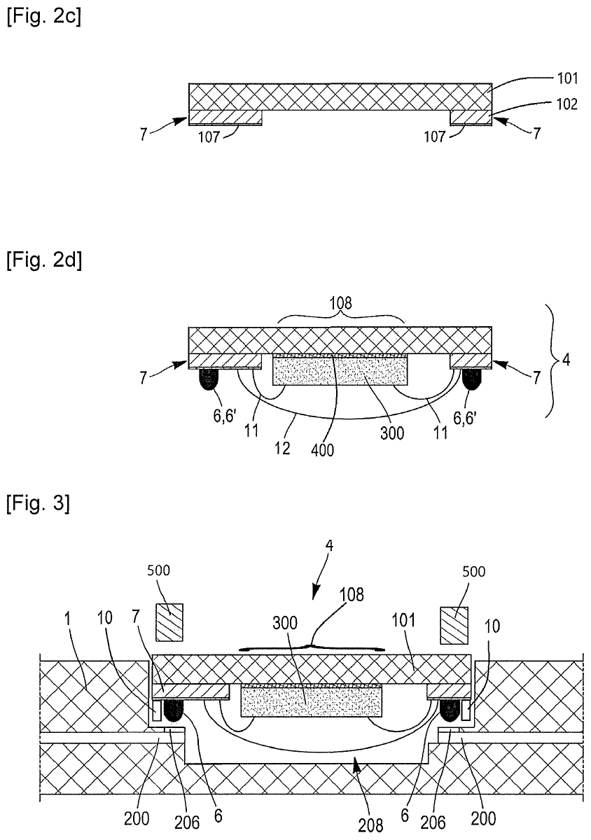

One example of a method for manufacturing a module of the type illustrated in FIG. 2 is described below.

This method comprises providing a complex material 100 comprising a substrate 101 made of dielectric material, on which a sheet consisting of an electrically conductive material 102 is laminated (see FIG. 2a). For example, the dielectric material is a polyimide the thickness of which is between 25 and 75 micrometres, and is preferably equal to 50 micrometres, and the first electrically conductive material 102 consists of copper or of a copper alloy the thickness of which is between 12 and 70 micrometres, and is preferably equal to 18 micrometres; for effective implementation of the method according to the invention on an industrial scale, this complex material 100 is advantageously provided in a reel and the method is implemented reel-to-reel. The complex material 100 may be provided in the form of a clad, for example a copper clad. As an alternative, it may be provided in the form of a multilayer complex 100 (not shown) comprising a dielectric material substrate 101, a sheet of electrically conductive material 102, and a layer of adhesive material (for example epoxy material) between the dielectric material substrate 101 and the sheet of electrically conductive material 102. The adhesive material has for example a thickness between 10 and 25 micrometres. This multilayer complex 100 undergoes lamination. The adhesive material possibly undergoes a continuous drying process in order to evacuate solvents present in the formulation when it is deposited. The layer of adhesive material thus makes it possible to fasten the sheet of electrically conductive material 102 to the inner face of the dielectric material substrate 101. The lamination may possibly be followed by a step of thermal crosslinking of the adhesive material.

The polyimide forming the substrate 101 is for example a thermostable polyimide (such as an aromatic polyimide). It is for example Kapton® B Black marketed by DuPont™ or Kymide® KYPI-B marketed by Kying®.

This is then followed by steps of a photolithography process for forming connection pads and tracks 7 (see FIG. 2b) in the sheet of electrically conductive material 102. These steps comprise for example a step of laminating a dry photosensitive resin film on the free surface of the sheet of electrically conductive material 102, and then insolating this photosensitive resin film through a mask, revealing the photosensitive resin and etching on certain areas of the sheet of electrically conductive material 102 so as to form connection pads, connection tracks or any other pattern 7.

As an alternative, connection pads and tracks 7 are formed by cutting or etching into the sheet of electrically conductive material 102 (using leadframe technology), before laminating them on the inner face of the dielectric substrate 101.

Advantageously, it is possible to perform electrolytic depositions of metal layers 107 (copper, nickel, gold, palladium, silver and alloys thereof for example) intended to make it easier to solder connection wires 11 to the electrically conductive material 102 (see FIG. 2c). Other conceivable technologies for connecting the sensor 300 to the connection pads and tracks 7 may also require one or more metallization steps.

More particularly, the connection pads and tracks 7 form a circuit comprising first connection pads that are electrically connected to the sensor 300 and that are located underneath an encapsulation 12 and second connection pads that are electrically connected to the first connection pads, these second pads being intended to connect the module 4 to a chip card circuit 200. These second pads are located outside the encapsulation 12 (see the description with reference to FIG. 2d further below). The first and second pads are possibly connected by conductor tracks so as to establish the required electrical continuity between the inside and the outside of the encapsulation 12.

According to one particular mode of implementation of the method according to the invention, a solder material 6 is deposited on connection pads 7 produced in the sheet of electrically conductive material 102 in the preceding steps (see FIG. 2d). For example, the solder material 6 is a tin-bismuth or tin-bismuth-silver alloy.

As an alternative, instead of depositing a solder material 6 on the connection pads 7, these are left untouched until the operation of embedding the module 4 in the card 1. Then, during the embedding operation, prior to installing the module 4 in the cavity 208 formed (for example by milling) in the card body, a solder material 6, a paste or an anisotropic conductive film 6′ is deposited on the connection pads 7 in order to establish a connection with the circuit 200 housed in the card body (see FIG. 3).

At the end of the above steps, a reel comprising biometric sensor supports for a chip card is obtained. Each of these supports has a structure corresponding for example to the one shown in FIG. 2d. Each support therefore comprises:
An outer face with a detection area 108 situated opposite an area of the inner face on which the sensitive elements of a detection element of a biometric sensor will rest;
An inner face with connection pads 7, possibly with a blob of solder material 6 deposited on at least some of these connection pads 7 in order to be able to subsequently connect a module 4 to a circuit 200 integrated into the card body (see FIG. 3).

For the purpose of being used and integrated into a chip card 1, each support is equipped with a biometric fingerprint sensor 300. Advantageously, the biometric sensor 300 is insensitive or only slightly sensitive to electrostatic charge. A bezel may thus be dispensed with. The method described above is then greatly simplified in comparison with methods from the prior art, in which a bezel has to be produced on the outer face and then electrically connected (for example using vias) to a circuit situated on the inner face.

This biometric sensor 300 is fastened to the back face for example using a known die attach technology. For example, the biometric sensor 300 is fastened to the back face of the support 101 using a thermosetting adhesive 400 that sets at temperatures between 100° C. and 150° C. and that has the property of migrating, through capillary action, under the entire surface of the sensor without generating any gaps or bubbles (“underfill”). For example, the thickness of the thermosetting adhesive 400 underneath the biometric sensor 300 is between 5 and 35 micrometres. This is for example an adhesive with an amine base, without any epoxy.

A solder material 6 is deposited on connection pads 7 before or after the biometric sensor 300 is assembled, but preferably after in order to avoid the solder material 6 melting during the crosslinking of the thermosetting adhesive 400, notably if said solder material is a low-temperature solder material.

The solder material 6 is deposited through screen printing or through jetting. The solder material 6 is preferably deposited on connection pads 7 by jetting if the biometric sensor 300 is already assembled on the dielectric support 101.

The biometric sensor 300, on the back face, occupies a surface area corresponding essentially to a detection area situated, on the inner face of the dielectric substrate 101, opposite the detection area 108. This biometric sensor 300 is connected to the connection pads 7 using a known technology, such as wire bonding using conductive wires 11, as shown in FIGS. 2d and 3. As an alternative, the biometric sensor 300 is connected to the connection pads 7 using flip-chip technology. Advantageously, the biometric sensor 300 and its possible conductive wires 11 are protected in the encapsulation 12, for example consisting of an encapsulating resin. A hotmelt adhesive 10 is possibly also arranged on the back face on or next to the connection pads 7. This hotmelt adhesive 10 is intended to fasten the biometric sensor module 4 in the cavity 208 formed in the body of a chip card (see FIG. 3).

When the module 4 is embedded in a card body, there are several possible options for establishing a connection between the connection pads 7 of the module 4 and the circuit 200 that is integrated into the card body. It is possible for example to solder the connection pads 7 directly to the circuit 200 using the solder material 6 deposited on the connection pads 7. As an alternative, it is possible to deposit blobs 206 of a solder material on the circuit 200 and form a connection between the solder pads 7 and the circuit 200 by melting one, the other or both solder materials that have been deposited beforehand, each respectively, on the connection pads 7 and on the circuit 200. More particularly, for example, it is possible to deposit a first solder material 6 on the connection pads 7 and a second solder material 206 on the circuit 200. The first solder material 6 is then advantageously a solder material having a low melting temperature (for example a melting temperature lower than or equal to 140° C.), the second solder material 206 advantageously having a melting temperature close or identical to that of the first solder material 6.

For example, to connect the connection pads 7 to the circuit 200, a thermode 500 is placed facing the connection pads 7 on either side of the support 101.

Using a first solder material 6 with a low melting temperature (lower than or equal to 140° C.) on the connection pads 7 and a second solder material 206 on the circuit 200 having a melting temperature equal to, close to or lower than that of the first solder material 6, the thermode 500, heated for example to a temperature of 230° C., is applied for 1.5 seconds. The method according to the invention is therefore faster in this case. Furthermore, using solder materials 6, 206 with a low melting temperature makes it possible to use a thermode 500 with a smaller carrier surface, thereby possibly helping to better control creep and to limit risks of deformation of the card 1 and/or of the module 4. This method using a low-temperature solder 206 is advantageous for example for card bodies made of PVC when the lamination temperature of the circuit 200 in the card with its solder 206 does not exceed 130° C.

Using a first solder material 6 with a low melting temperature (lower than or equal to 140° C.) on the connection pads 7 and a second solder material 206 with a higher melting temperature on the circuit 200, the thermode 500, heated for example to a temperature of 230° C., is applied for 2.5 seconds. The heat provided by the thermode 500 also dissipates into the hotmelt adhesive 10 so as to adhesively bond the module 4 in the card 1.

This method using a solder material 206 with a high melting temperature is advantageous for example for card bodies made of polycarbonate when the lamination temperature of the circuit 200 in the card with its solder 206 may range up to 190° C.

Generally speaking, it is possible to use an electrically conductive adhesive or paste 6′, an anisotropic conductive film or a solder material 6 to connect the module 4 to the circuit 200. However, in any case, the method described above or variants thereof are advantageously used by producing connection pads 7 having a shape that is compatible both with the use of a solder material 6 and with a paste or an anisotropic conductive film 6′, this shape possibly being rectangular, rhomboidal, square, an oval or a disc shape, and also with radial or lateral extensions. The module 4 according to the invention is then the same whether it is connected through soldering or using a conductive adhesive. This makes it possible to manufacture the module 4 in larger runs, while still leaving the embedder the option of choosing one or the other of the connection technologies.

For aesthetic reasons and/or to indicate the location of the detection area on which the finger should be placed in order to detect its fingerprint, the dielectric substrate 101 is advantageously bulk-coloured. For example, the dielectric substrate 101 is a polyimide coloured black using a pigment or a dye.

1. Biometric sensor module for a chip card including
a dielectric substrate having an outer face and an inner face, each situated respectively on either side of this dielectric substrate considered along its thickness, the inner and outer faces of the dielectric substrate corresponding to the main faces thereof,
tracks and connection pads formed in a sheet of electrically conductive material that rests on the inner face of the dielectric substrate and is fastened thereto,
a biometric sensor with a detection element formed of sensitive elements, this sensor being connected to at least some connection pads, and being fastened to an area of the inner face that does not have any electrically conductive material, an area of the outer face situated opposite the detection element corresponding to a biometric detection area configured such that a finger placed on it establishes contact therewith, and
an encapsulation deposited at least on the sensor, on the side of the inner face of the dielectric substrate,
characterized in that, at least over the detection area, the outer face of the dielectric substrate corresponds to a homogeneous polymer material that is exposed and that has a glass transition temperature greater than or equal to 110 degrees Celsius.

2. Module according to claim 1, wherein the dielectric substrate consists of the homogeneous polymer material left exposed at least over the detection area.

3. Module according to claim 1, wherein the homogeneous polymer material is chosen from among the following materials: a polyimide, a polyethylene naphthalate (PEN) and a polyetheretherketone (PEEK).

4. Module according to claim 1, wherein the homogeneous polymer material has a thickness between 25 and 75 micrometres, and more preferably has a thickness close to 50 micrometres.

5. Module according to claim 1, wherein the homogeneous polymer material is bulk-coloured.

6. Module according to claim 1, wherein the sensor is fastened to the inner face of the dielectric substrate using an adhesive layer the thickness of which is between 5 and 35 micrometres.

7. Module according to claim 1, having first connection pads that are electrically connected to the sensor and that are located underneath the encapsulation and second connection pads that are electrically connected to the first connection pads, these second pads being intended to connect the module to a chip card circuit and being located outside the encapsulation.

8. Module according to claim 1, wherein the outer face does not have a bezel surrounding the detection area.

9. Chip card comprising a card body with an electrical circuit integrated into the card body and a module according to one of the preceding claims, the module and the circuit being electrically connected using a solder material deposited on the second connection pads.

10. Method for manufacturing a biometric sensor module for a chip card, comprising steps of
providing a dielectric substrate having an outer face and an inner face, each situated respectively on either side of this dielectric substrate considered along its thickness, the inner and outer faces of the dielectric substrate corresponding to the main faces thereof,
forming tracks and connection pads in a sheet of electrically conductive material before or after this sheet of electrically conductive material has been fastened to the inner face of the dielectric substrate,
fastening a biometric sensor with a detection element formed of sensitive elements to an area of the inner face that does not have any electrically conductive material, an area of the outer face situated opposite the detection element corresponding to a biometric detection area configured such that a finger placed on it establishes contact therewith,
connecting the sensor to at least some pads, and
encapsulating the sensor in an encapsulation,
characterized in that, at least over the detection area, the outer face of the dielectric substrate corresponds to a homogeneous polymer material that is exposed and that has a glass transition temperature greater than or equal to 110 degrees Celsius.
